(19) United States
(12) Patent Application Publication
(10) Pub. No.: US 2026/0343768 A1
(43) Pub. Date: Oct. 29, 2026

(54) Electronic Device With Coatings on Curved Substrates

(71) Applicant: Apple Inc., Cupertino, CA (US)

(72) Inventors: Tyler R Roschuk, Morgan Hill, CA (US); Andi M Limarga, Cupertino, CA (US); Dale N Memering, Waterloo (CA); Matthew J Gutwald, San Francisco, CA (US); Matthew S Rogers, San Jose, CA (US); Que Anh S Nguyen, San Jose, CA (US); Ove Lyngnes, Carmel Valley, CA (US); Vijayen S Veerasamy, Sunnyvale, CA (US)

(21) Appl. No.: 19/575,754

(22) Filed: Mar. 23, 2026

Related U.S. Application Data
(60) Provisional application No. 63/794,547, filed on Apr. 25, 2025.
(60) Provisional application No. 63/931,353, filed on Dec. 4, 2025.

(51) Int. Cl. H05K 5/03

(52) U.S. Cl. CPC H05K 5/03

(57) ABSTRACT

An electronic device may have a housing surrounding an interior in which electrical components are mounted. A display may be mounted to the housing. The housing may have one or more curved housing portions, such as a display cover layer overlapping the display and/or a rear housing wall. A hardcoat and anti-reflective coating may be formed on the curved housing portion(s). The hardcoat and anti-reflective coating may have a uniform thickness across the curved housing portion(s) or may be tapered across curved portion(s). A buffer layer may be interposed between the hardcoat and anti-reflective coating and the curved portion, if desired. The hardcoat and anti-reflective coating may be formed from a single layer hardcoat or may be formed from multiple layers, including one or more hardcoat layers and one or more anti-reflective layers. One or more layers of the hardcoat and anti-reflective coating may be formed from a nanolaminate.

This application claims the benefit of U.S. provisional patent application No. 63/931,353, filed Dec. 4, 2025, and claims the benefit of U.S. provisional patent application No. 63/794,547, filed Apr. 25, 2025, which are hereby incorporated by reference herein in their entireties.

### FIELD

This relates generally to electronic devices, including electronic devices with housings.

### BACKGROUND

Electronic devices such as cellular telephones, computers, watches, and other devices may contain housing structures and components within the housing structures. For example, electronic devices may have displays in which an array of pixels is covered with a display cover layer and/or may have a rear housing wall.

### SUMMARY

An electronic device may have a housing in which a display is mounted. The housing may be formed from housing structures that surround an interior region in the electronic device. Electrical components may be mounted in the electronic device interior.

The display may be coupled to the housing structures on a front face of the electronic device. The housing may have one or more curved housing portions, such as a display cover layer overlapping the display and/or a rear housing wall opposite the display.

A hardcoat and anti-reflective coating may be formed on the one or more curved housing portions. The hardcoat and anti-reflective coating may have a uniform thickness across the curved housing portions or may be tapered across curved portions. If desired, a buffer layer may be interposed between the hardcoat and anti-reflective coating and the curved housing portion.

The hardcoat and anti-reflective coating may be formed from a single hardcoat layer or may be formed from multiple layers, including one or more hardcoat layers and one or more sets of anti-reflective layers. The anti-reflective layers may be below, within, or on top of the one or more hardcoat layers. One or more layers of the hardcoat and anti-reflective coating may be formed from a nanolaminate that includes a plurality of layers with nanoscale thicknesses to provide optical performance and sufficient hardness.

### BRIEF DESCRIPTION OF THE DRAWINGS

FIG. 1 is a perspective view of an illustrative electronic device in accordance with some embodiments.

FIG. 2 is a side view of an illustrative electronic device having transparent layers forming housing walls in accordance with some embodiments.

FIG. 3A is a side view of a curved housing portion with a uniform hardcoat and anti-reflective coating in accordance with some embodiments.

FIG. 3B is a side view of a curved housing portion with a tapered hardcoat and anti-reflective coating in accordance with some embodiments.

FIG. 3C is a side view of a curved housing portion with a buffer layer between a hardcoat and anti-reflective coating and the curved housing portion in accordance with some embodiments.

FIG. 4 is a side view of an illustrative single layer hardcoat on a housing portion in accordance with some embodiments.

FIG. 5 is a side view of an illustrative hardcoat and anti-reflective coating with a hardcoat layer interposed between an anti-reflective layer and a housing portion in accordance with some embodiments.

FIG. 6 is a side view of an illustrative hardcoat and anti-reflective coating with an anti-reflective layer interposed between two hardcoat layers on a housing portion in accordance with some embodiments.

FIG. 7 is a side view of an illustrative hardcoat and anti-reflective coating with an anti-reflective layer interposed between a hardcoat layer and a housing portion in accordance with some embodiments.

FIG. 8 is a side view of an illustrative hardcoat and anti-reflective coating with a hardcoat layer interposed between two anti-reflective layers on a housing portion in accordance with some embodiments.

FIG. 9 is a side view of an illustrative nanolaminate that may be used to form one or more layers of a hardcoat or a hardcoat and anti-reflective coating in accordance with some embodiments.

### DETAILED DESCRIPTION

Electronic devices may include housing walls, such as display cover layers or rear housing walls. These housing walls may be formed from glass, ceramic, sapphire, and/or another suitable material. The housing walls may be curved. For example, the housing walls may be curved across an entirety of the housing walls or at one or more edges of the housing walls. The curvature of the housing walls may be simple curvature or complex curvature.

The housing walls may be coated with a coating to reduce scratches and to reduce reflections. Therefore, the housing walls may be coated with a hardcoat and anti-reflective coating. The hardcoat and anti-reflective coating may be formed in a hardcoat layer or may be formed with multiple layers, including one or more hardcoat layer and one or more sets of anti-reflective layers. The anti-reflective layers may be below, within, or on top of the one or more hardcoat layers. The coating may be applied uniformly across the curved housing walls, or the coating may be tapered with a graded thickness in the curved regions. Alternatively or additionally, a buffer layer may be interposed between the housing walls and the coating.

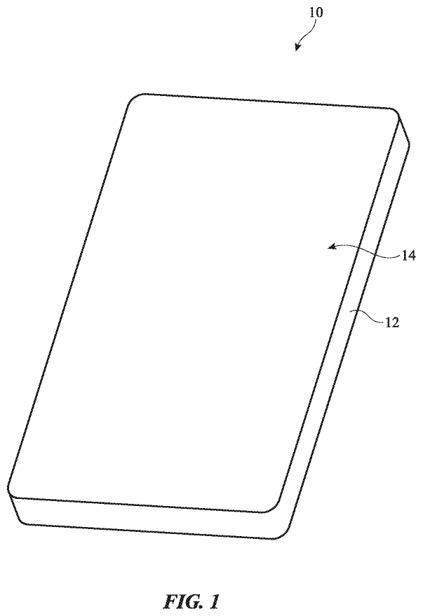

An illustrative electronic device of the type that may have one or more housing portions with a hardcoat and anti-reflective coating is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head (e.g., a head-mounted device), or other wearable or miniature device, a television, a computer display that does not contain an embedded computer, a gaming device, a navigation device, an embedded system such as a system in which electronic equipment with a display is mounted in a kiosk or automobile, equipment that implements the functionality of two or more of these devices, an accessory (e.g., earbuds, a remote control, a wireless trackpad, etc.), or other electronic equipment. In the illustrative configuration of FIG. 1, device 10 is a portable device such as a cellular telephone, media player, tablet computer, or other portable computing device. Other configurations may be used for device 10 if desired. The example of FIG. 1 is merely illustrative.

In the example of FIG. 1, device 10 includes a display such as display 14 mounted in housing 12. Housing 12, which may sometimes be referred to as an enclosure or case, may be formed of plastic, glass, ceramics, fiber composites, metal (e.g., stainless steel, aluminum, titanium, gold, etc.), other suitable materials, or a combination of any two or more of these materials. Housing 12 may be formed using a unibody configuration in which some or all of housing 12 is machined or molded as a single structure or may be formed using multiple structures (e.g., an internal frame structure, one or more structures that form exterior housing surfaces, etc.).

Display 14 may be a touch screen display that incorporates a layer of conductive capacitive touch sensor electrodes or other touch sensor components (e.g., resistive touch sensor components, acoustic touch sensor components, force-based touch sensor components, light-based touch sensor components, etc.) or may be a display that is not touch-sensitive. Capacitive touch screen electrodes may be formed from an array of indium tin oxide pads or other transparent conductive structures.

Display 14 may include an array of pixels formed from liquid crystal display (LCD) components, an array of electrophoretic pixels, an array of plasma pixels, an array of organic light-emitting diode (OLED) pixels or other light-emitting diodes (e.g., microLEDs), an array of electrowetting pixels, or pixels based on other display technologies.

Display 14 may include one or more layers of transparent material. For example, the outermost layer of display 14, which may sometimes be referred to as a display cover layer, may be formed from a hard transparent material such as glass, ceramic, sapphire, or other suitable material to help protect display 14 from damage. If desired, the display cover layer may form a front housing wall of housing 12. Other portions of device 10 such as portions of housing 12 and/or other structures may also be formed from a transparent material. For example, walls in housing 12 such as a rear housing wall and/or side walls may be formed from glass, ceramic, sapphire, or other suitable material.

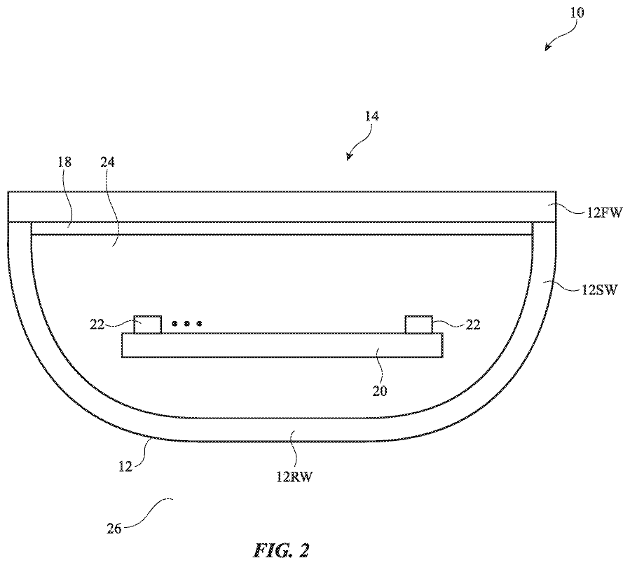

A cross-sectional side view of device 10 is shown in FIG. 2. As shown in FIG. 2, device 10 may have an interior 24 in which electrical components 22 are housed. Electrical components 22 may include integrated circuits, sensors, and other circuitry. As examples, electrical components 22 may form wireless communications circuitry, wireless charging circuitry, processing circuitry, and/or display circuitry, as examples. In general, any desired circuitry may be formed in device 10. Components 22 may be mounted on one or more printed circuits such as printed circuit 20.

As shown in FIG. 2, device 10 may have opposing front and rear faces. Display 14 may be formed on the front face of device 10 (e.g., display 14 may face a front of device 10) and may be covered by a display cover layer 12FW (also referred to as front housing wall 12FW herein). Housing 12, which separates interior 24 from exterior 26, may have a rear housing wall 12RW (also referred to as rear cover layer 12RW herein) on the opposing rear face of device 10 (e.g., rear housing wall 12RW may face a rear of device 10). At least portions of one or both of display cover layer 12FW and rear housing wall 12RW may be formed from a transparent material, such as glass, ceramic, sapphire, or other suitable material. For example, an entirety of one or both of display cover layer 12FW and rear housing wall 12RW may be formed from transparent material, such as glass. However, this is merely illustrative. In general, any desired portion of display cover layer 12FW and/or rear housing wall 12RW may be formed from transparent material. Alternatively, at least portions of display cover layer 12FW, housing wall 12RW, and/or other portions of housing 12 may be formed from non-transparent material, such as opaque material, transparent material coated with a non-transparent coating, etc.

Portions of housing 12 may also form sidewalls 12SW for device 10. These sidewall portions of housing 12 may be formed from a material such metal, may be formed from glass, may be formed from the same layer as rear housing wall 12RW, and/or may be formed from the same layer as display cover layer 12FW, as examples. Display cover layer 12FW, rear housing wall 12RW, and/or sidewalls 12SW may be formed from transparent material, if desired. Some or all of display cover layer 12FW, rear housing wall 12RW, and/or sidewalls 12SW may be curved, while some or all of the walls may be planar, as desired.

Display 14 may include a display cover layer (e.g., a layer of glass) that forms front housing wall 12FW of housing 12 and may include display module 18 (e.g., display layers that form an array of pixels that present images for a user on the front face of device 10). Display module 18 may be a liquid crystal display structure, an organic light-emitting diode display structure, a microLED display structure, or another suitable display. During operation, display module 18 may present images that are viewable through display cover layer 12FW. The rear of the housing for device 10 may be formed from a glass structure (e.g., rear housing wall 12RW may formed from a glass layer). The thickness of rear housing wall 12RW may be 0.2-5 mm, at least 0.05 mm, at least 0.1 mm, at least 0.2 mm, at least 0.5 mm, at least 0.75 mm, less than 1 mm, less than 2 mm, or another suitable thickness. If desired, a metal plate or other strengthening structures may be laminated to portions of the inner surface of rear housing wall 12RW and/or sidewalls 12SW to enhance the strength of the housing walls.

Inactive border areas in display cover layer 12FW (e.g., areas through which display module 18 does not display images) and portions of other glass structures in device 10 such as some or all of rear housing wall 12RW and/or sidewalls 12SW may be covered with coatings and other structures. In some arrangements, a coating may be used primarily to block light (e.g., to hide internal device structures from view). For example, a coating may be formed on the inner surface of rear housing wall 12RW to hide internal components from view from a user. In other arrangements, a patterned coating may be used to form text, logos, trim, and/or other visible patterns. Coatings that are unpatterned and that coat all of rear housing wall 12RW and/or sidewalls 12SW may also be used to block internal structures from view and/or to provide device 10 with a desired appearance. Patterned coatings may create visible elements and may also block internal structures from view.

Coatings for glass structures in device 10 may be black or other neutral colors or may have non-black (non-neutral) colors (e.g., blue, red, yellow, gold, rose gold, red-violet, pink, etc.). In some configurations, some or all of the coatings for glass structures in device 10 may be shiny (e.g., exhibiting a mirror-like reflective surface with a reflectance of at least 50%, at less 80%, at least 95%, less than 99.99%, or other suitable reflectance).

Coatings on rear housing wall 12RW and/or other glass structures in device 10 may be formed from metals, semiconductors, and/or dielectrics. Dielectric materials for the coatings may include organic materials such as polymer layers and/or inorganic materials such as oxide layers, nitride layers, and/or other inorganic dielectric materials. In arrangements in which a shiny surface is desired, a metal coating with a high reflectivity or a thin-film interference filter with dielectric layers (e.g., a stack of dielectric layers of alternating higher and lower refractive index values) may be configured to serve as a mirror coating (reflective coating). Ink coatings may also be incorporated onto the glass structures, if desired.

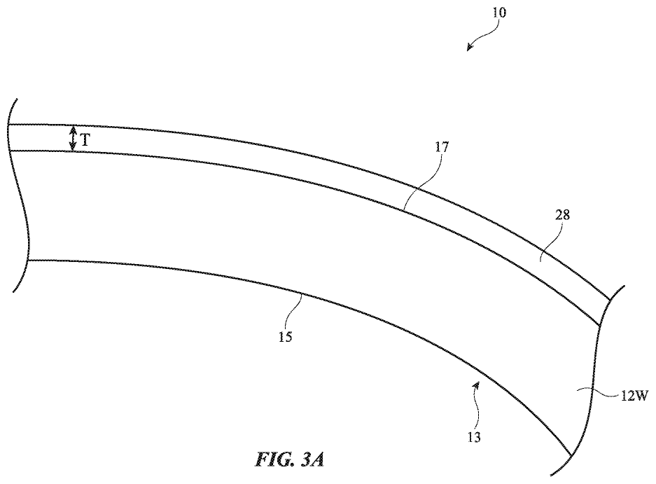

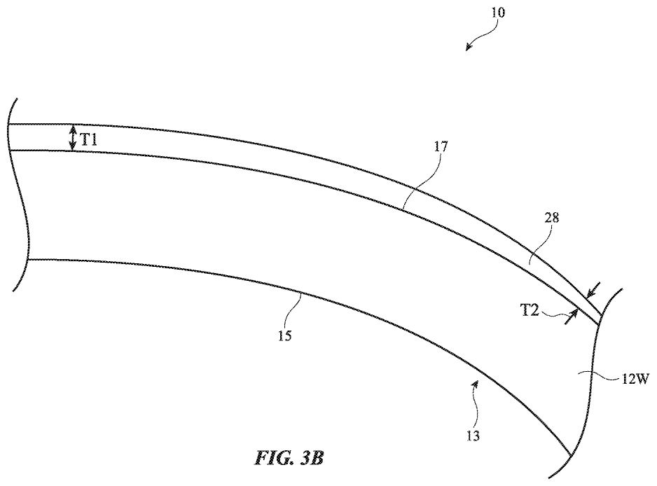

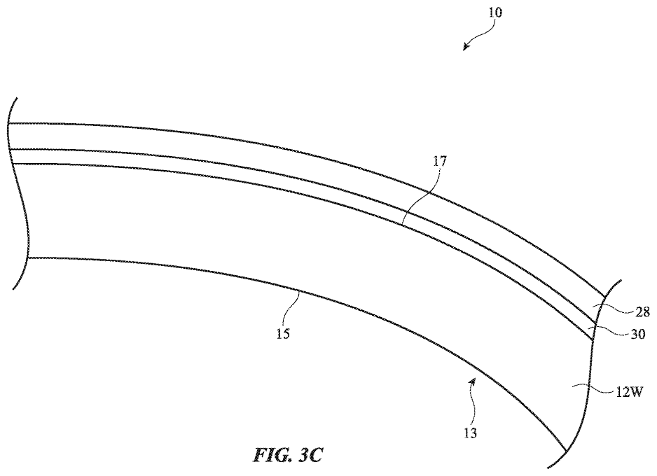

In some embodiments, one or more portions of housing 12, such as front housing wall 12FW and/or rear housing wall 12RW, may be curved. For example, the portion(s) of housing 12 may have curved edges and/or other portions with curvature. It may be desirable to increase the scratch resistance of the curved portion(s) of the housing and to reduce reflections from the curved portion(s) of the housing. Therefore, one or more curved portions of the housing may be coated with a hardcoat and anti-reflective coating. An illustrative example is shown in FIG. 3A.

As shown in FIG. 3A, device 10 may include housing wall 12W (also referred to as housing portion 12W herein). Housing wall 12W may be formed from glass, plastic, polycarbonate, ceramic, sapphire, acrylic, polymer, or another suitable material. Housing wall 12W may have surface 15 and surface 17. Surface 15 may be an inner surface that faces an interior of device 10 (e.g., interior 24 of FIG. 2), and surface 17 may be an outer surface that faces an exterior of device 10 (e.g., exterior 26 of FIG. 2).

Housing wall 12W may be a curved housing wall. For example, housing wall 12W may have curved edge 13 (e.g., at a periphery of housing wall 12W). In some embodiments, housing wall 12W may have one or more planar portions, such as a central portion, and one or more curved portions, such as one or more curved edges. However, this is merely illustrative. An entirety of housing wall 12W may be curved, if desired.

Regardless of what portion(s) of housing wall 12W are curved, the portion(s) may have simple curvature (e.g., housing wall 12W may be curved along a single axis and can therefore be flattened into a plane without distortion) or may have compound curvature (e.g., one or both surfaces 15 and 17 may be non-developable surfaces that cannot be flattened into a plane without distortion).

Hardcoat and anti-reflective coating 28 (also referred to as coating 28 herein) may be formed on (e.g., directly on) surface 17 of housing portion 12W. Hardcoat and anti-reflective coating 28 may be both a hardcoat, being formed from a material that is harder than housing portion 12W, and an anti-reflective coating, being formed from a material that reduces reflections from housing portion 12W (e.g., a material with an index of refraction between the index of refraction of housing portion 12W and the refractive index of air).

Hardcoat and anti-reflective coating 28 may include one or more coating layers. In some illustrative example, hardcoat and anti-reflective coating 28 may be a single hardcoat layer. Therefore, the single layer may include a silicon oxynitride, a silicon aluminum nitride, a silicon aluminum oxide, aluminum oxide, aluminum nitride, silicon oxide, silicon nitride, and/or other suitable materials.

In the example of FIG. 3A, coating 28 has a uniform thickness across surface 17 of housing portion 12W. For example, coating 28 may have thickness T that varies less than 5%, less than 3%, or less than 1%, as examples, across surface 17, including across curved edge 13 of housing portion 12W. Therefore, coating 28 may provide uniform scratch protection across surface 17.

In some embodiments, it may be desirable to reduce the thickness of coating 28 at the curved portion(s) of housing portion 12W. An illustrative example is shown in FIG. 3B.

As shown in FIG. 3B, coating 28 may have a first thickness T1 in the one or more portions of housing portion 12W that do not overlap curved edge 13 and may have a second thickness T2 at curved edge 13. Second thickness T2 may differ from first thickness T1 by more than 10%, more than 25%, more than 50%, or another suitable amount. The thickness of coating 28 may taper (e.g., gradually reduce) between first thickness T1 and second thickness T2 across curved edge 13.

Although FIG. 3B shows coating 28 being tapered at curved edge 13, this is merely illustrative. In general, coating 28 may taper across any curved portion(s) of housing portion 12W. In this way, coating 28 may be thinner in area(s) of housing portion 12W with high stress (e.g., the curved portion(s) of housing portion 12W), allowing the high-stress portions of housing portion 12W to retain strength when coating 28 is applied to housing portion 12W.

Regardless of whether coating 28 has a uniform thickness across housing portion 12W (as shown in FIG. 3A) or a tapered thickness (as shown in FIG. 3B), a buffer layer may be provided between housing portion 12W and coating 28. An illustrative example is shown in FIG. 3C.

As shown in FIG. 3C, buffer layer 30 may be formed between housing portion 12W and coating 28. For example, buffer layer 30 may be on (e.g., directly on) surface 17 of housing portion 12W, and coating 28 may be on (e.g., directly on) buffer layer 30. Buffer layer 30 may be a buffer layer with a low modulus of elasticity and may be formed from a silicon oxycarbide, a silicon oxyhydride, a compound with a chemical formula of SiOₓN_{y}C_{z}, a compound with a chemical formula of SiOxNyCz:H, or another suitable material. In this way, buffer layer 30 may reduce or prevent strength degradation of housing portion 12W when coating 28 is formed on housing portion 12W.

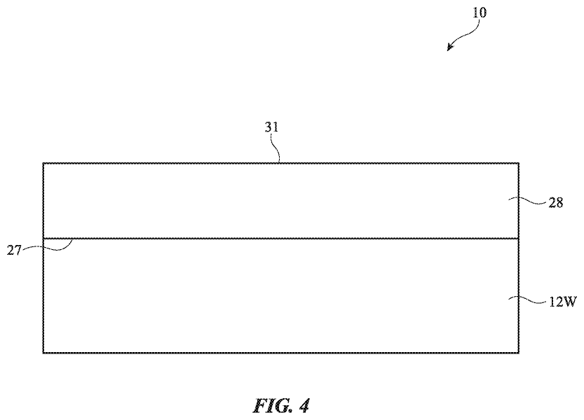

In general, hardcoat and anti-reflective coating 28 may include one or more layers. For example, hardcoat and anti-reflective coating 28 may include a single hardcoat layer. An illustrative example is shown in FIG. 4.

As shown in FIG. 4, coating 28 is a single layer on housing portion 12W. Therefore, coating 28 may be formed from a hardcoat material. As illustrative examples, coating 28 may be formed from a silicon oxynitride (e.g., SiON), a silicon aluminum nitride (e.g., SiAlN), or another suitable material. In some embodiments, coating 28 may be formed from a mixture of materials. The one or more materials that form coating 28 may be harder (e.g., have a higher Mohs hardness) than housing portion 12W to provide hardcoat properties. Therefore, coating 28 may be a single layer hardcoat on housing portion 12W.

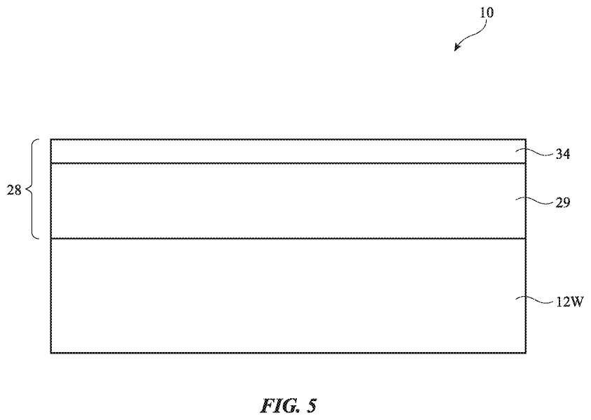

In other embodiments, coating 28 may be formed from two or more layers. An illustrative example is shown in FIG. 5.

As shown in FIG. 5, coating 28 may include hardcoat layer 29 and anti-reflective layer 34. Hardcoat layer 29 may be formed from any suitable material that is harder (e.g., has a higher Mohs hardness value) than housing portion 12W to provide hardcoat properties.

Anti-reflective layer 34 may be formed from silicon oxide, silicon nitride, or another suitable material with an index of refraction between the refractive index of exterior of device 10 (e.g., a refractive index of 1 corresponding to air) and the refractive index of housing portion 12W to provide anti-reflective properties. However, this is merely illustrative. In general, anti-reflective layer 34 may be formed from a single layer or may be formed from multiple layers, such as multiple thin-film layers (e.g., thin-film dielectric layers), which may have different refractive indexes.

In some embodiments, anti-reflective layer 34 may have an index of refraction gradient that varies between a first index of refraction that matches (or is close to) the index of refraction of air or another low refractive index (e.g., SiO₂ or lower index SiON) and a second index of refraction that matches (or is close to) the index of refraction of housing portion 12W. For example, anti-reflective layer 34 may have a continuous, smooth refractive index gradient between the first and second indexes of refraction, or anti-reflective layer 34 may have another suitable refractive index gradient, such as a stepwise gradient. Anti-reflective layer 34 may have the refractive index gradient within a single layer or across multiple layers (e.g., each layer may have a different refractive index to form the refractive index gradient).

Hardcoat layer 29 may have a refractive index that is higher than the refractive index of anti-reflective layer 34 and higher than the refractive index of housing portion 12W. However, this is merely illustrative. In some embodiments, hardcoat layer 29 may have a refractive index between the refractive index of anti-reflective layer 34 and housing portion 12W to improve the anti-reflective properties of coating 28, if desired. In general, anti-reflective layer 34 and hardcoat layer 29 may have suitable refractive indexes to form hardcoat and anti-reflective coating 28 on housing portion 12W.

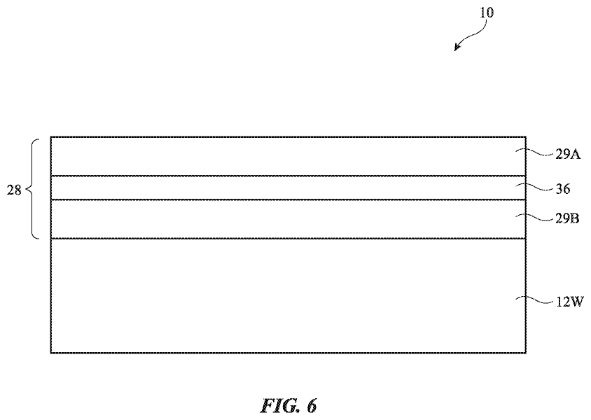

Although FIG. 5 shows hardcoat layer 29 interposed between anti-reflective layer 34 and housing portion 12W, this is merely illustrative. In general, hardcoat layer 29 may include one or more hardcoat layers and one or more anti-reflective layers, and the hardcoat layer(s) and anti-reflective layer(s) may be stacked in any suitable manner. An illustrative example is shown in FIG. 6.

As shown in FIG. 6, coating 28 may include two hardcoat layers 29A and 29B and anti-reflective layer 36 between hardcoat layers 29A and 29B. Hardcoat layers 29A and 29B may be formed from any suitable material that is harder (e.g., has a higher Mohs hardness value) than housing portion 12W to provide hardcoat properties.

Anti-reflective layer 36 may be formed from silicon oxide, silicon nitride, or another suitable material with a low index of refraction. In some embodiments, anti-reflective layer 36 may have an index of refraction between the refractive index of exterior of device 10 (e.g., a refractive index of 1 corresponding to air) and the refractive index of housing portion 12W. For example, anti-reflective layer 36 may have an index of refraction between a refractive index of hardcoat layer 29A and a refractive index of hardcoat layer 29B (or housing portion 12W), if desired. However, this is merely illustrative. In general, anti-reflective layer 36 may have any suitable refractive index to provide anti-reflective properties. Additionally, anti-reflective layer 36 may be formed from a single layer or may be formed from multiple layers, such as multiple thin-film layers (e.g., thin-film dielectric layers), which may have different refractive indexes.

In some embodiments, anti-reflective layer 36 may have an index of refraction gradient that varies between a first index of refraction that matches (or is close to) the index of refraction of hardcoat layer 29A and a second index of refraction that matches (or is close to) the index of refraction of hardcoat layer 29B. However, this is merely illustrative. In general, anti-reflective layer 36 may have refractive index gradient between any low and high refractive indexes. For example, anti-reflective layer 36 may have a continuous, smooth refractive index gradient between the first and second indexes of refraction, or anti-reflective layer 36 may have another suitable refractive index gradient, such as a stepwise gradient. Anti-reflective layer 36 may have the refractive index gradient within a single layer or across multiple layers (e.g., each layer may have a different refractive index to form the refractive index gradient).

Hardcoat layer 29B may have a refractive index between the refractive index of anti-reflective layer 36 and housing portion 12W to improve the anti-reflective properties of coating 28, if desired. In this way, anti-reflective layer 36 and hardcoat layers 29A and 29B may form hardcoat and anti-reflective coating 28 on housing portion 12W.

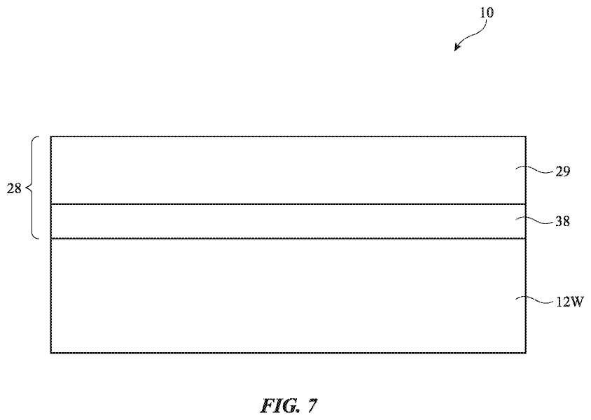

In some embodiments, coating 28 may include an anti-reflective layer between a hardcoat layer and housing portion 12W. An illustrative example is shown in FIG. 7.

As shown in FIG. 7, coating 28 may include anti-reflective layer 38 between hardcoat layer 29 and housing portion 12W. Anti-reflective layer 38 may be formed from silicon oxide, silicon nitride, or another suitable material with an index of refraction between the refractive index of hardcoat layer 29 and the refractive index of housing portion 12W to provide anti-reflective properties. However, this is merely illustrative. In general, anti-reflective layer 38 may be formed from a single layer or may be formed from multiple layers, such as multiple thin-film layers (e.g., thin-film dielectric layers), which may have different refractive indexes.

In some embodiments, anti-reflective layer 38 may have an index of refraction gradient that varies between a first index of refraction that matches (or is close to) the index of refraction of air or the index of refraction of hardcoat layer 29 and a second index of refraction that matches (or is close to) the index of refraction of housing portion 12W. For example, anti-reflective layer 38 may have a continuous, smooth refractive index gradient between the first and second indexes of refraction, or anti-reflective layer 38 may have another suitable refractive index gradient, such as a stepwise gradient. In this way, anti-reflective layer 38 and hardcoat layer 29 may form hardcoat and anti-reflective coating 28 on housing portion 12W. Anti-reflective layer 38 may have the refractive index gradient within a single layer or across multiple layers (e.g., each layer may have a different refractive index to form the refractive index gradient).

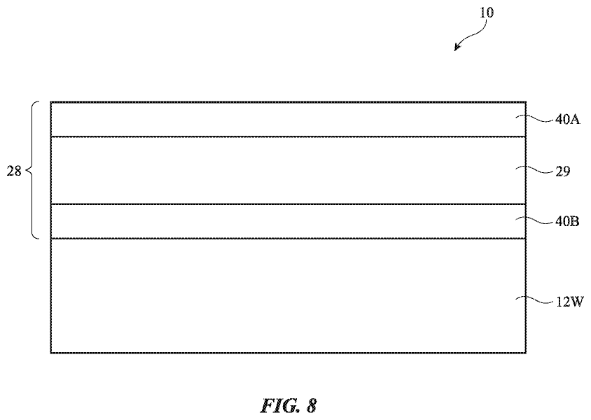

In some embodiments, coating 28 may include multiple anti-reflective layers. An illustrative example is shown in FIG. 8.

As shown in FIG. 8, coating 28 may include two anti-reflective layers 40A and 40B and hardcoat layer 29 interposed between anti-reflective layers 40A and 40B. Anti-reflective layers 40A and 40B may be formed from silicon oxide, silicon nitride, or other suitable material(s) with an index of refraction between the refractive index of exterior of device 10 (e.g., a refractive index of 1 corresponding to air) and the refractive index of housing portion 12W to provide anti-reflective properties. However, this is merely illustrative. In general, anti-reflective layers 40A and 40B may each be formed from a single layer or may each be formed from multiple layers, such as multiple thin-film layers (e.g., thin-film dielectric layers), which may have different refractive indexes.

More specifically, anti-reflective layer 40A may have an index of refraction between the refractive index of the exterior of device 10 (e.g., air) and the refractive index of hardcoat layer 29. Anti-reflective layer 40B may have an index of refraction between a refractive index of hardcoat layer 29 and a refractive index of housing portion 12W. Therefore, anti-reflective layers 40A and 40B may have different refractive indexes. However, this is merely illustrative. Anti-reflective layers 40A and 40B may have the same refractive index, if desired.

In some embodiments, anti-reflective layers 40A and 40B have graded refractive indexes. For example, anti-reflective layer 40A may have an index of refraction gradient that varies between a first index of refraction that matches (or is close to) the index of refraction of air or to another low refractive index, such as SiO₂, and a second index of refraction that matches (or is close to) the index of refraction of hardcoat layer 29. Anti-reflective layer 40B may have a first index of refraction that matches (or is close to) the index of refraction of hardcoat layer 29 and a second index of refraction that matches (or is close to) the index of refraction of housing portion 12W (e.g., with an intervening high refractive index). For example, anti-reflective layers 40A and 40B may have continuous, smooth refractive index gradients between the first and second indexes of refraction, or anti-reflective layers 40A and 40B may have another suitable refractive index gradient, such as a stepwise gradient. In this way, anti-reflective layers 40A and 40B and hardcoat layer 29 may form hardcoat and anti-reflective coating 28 on housing portion 12W. Anti-reflective layers 40A and 40B may each have refractive index gradients within a single layer or across multiple layers (e.g., each layer may have a different refractive index to form the refractive index gradient).

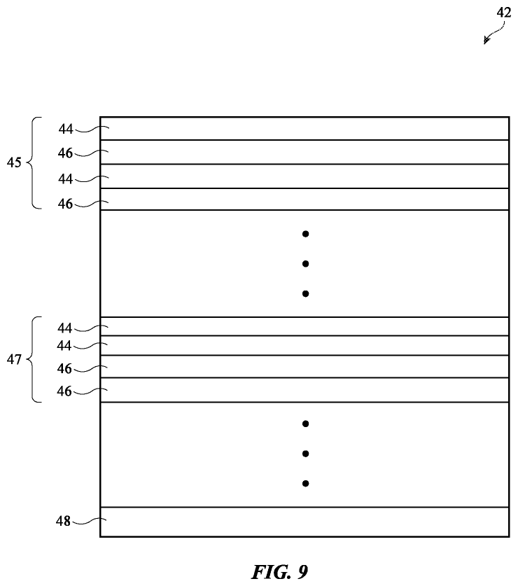

In some embodiments, one or more of the layers of coating 28 may be replaced by a nanolaminate that includes multiple layers of thin materials with nanoscale thicknesses. For example, coating 28 (FIG. 4), hardcoat layer 29 and/or anti-reflective layer 34 (FIG. 5), anti-reflective layer 36 and/or hardcoat layer(s) 29A/B (FIG. 6), anti-reflective layer 38 and/or hardcoat layer 29 (FIG. 7), and/or hardcoat layer 29 and/or anti-reflective layer(s) 40A/B (FIG. 8) may be replaced by a nanolaminate. An illustrative example of a nanolaminate that may be used to form one or more of these layers is shown in FIG. 9.

As shown in FIG. 9, nanolaminate 42 may include layers 44, 46, and/or 48. Layers 44 may include, for example, SiO₂ layers and/or other layers with low refractive indexes. Layers 46 may include, for example, SiN layers, Si₃N₄ layers, Nb₂O₅ layers, Al₂O₃ layers, AlN layers, ZrO₂ layers, or other layers with high refractive indexes. In other words, layers 44 and 46 may be alternating layers with high and low refractive indexes. Layers 44 and 46 may have nanoscale thicknesses of less than 30 nm, of 25 nm or less, of between 1 nm and 25 nm, of at least 1 nm, of between 5 nm and 15 nm, or other suitable thicknesses.

In some implementations, layers 44 of nanolaminate 42 may be SiO₂ layers and layers 46 may be SiN layers. Layers 44 and 46 may alternate throughout nanolaminate 42 (e.g., as shown in portion 45 of FIG. 9) from the top of nanolaminate 42 to the bottom of nanolaminate 42. In this way, nanolaminate 42 may replace an SiON layer and provide better antireflection properties (e.g., a lower refractive index than SiN) with higher hardness (e.g., higher hardness than SiO₂). However, the use of SiO₂ and SiN is merely illustrative. In general, nanolaminate 42 may include alternating layers of any suitable materials, such as SiOxNy layers to replace an SiON layer in coating 28.

Although FIG. 9 shows layer 44 as an uppermost layer of nanolaminate 42, this is merely illustrative. In some embodiments, layer 46 may form an upper most layer of nanolaminate 42. Similarly, layer 44, layer 46, or another suitable layer may form a lowermost layer of nanolaminate 42.

The use of alternating layers 44 and 46 is merely illustrative. Instead of, or in addition to, including alternating layers 44 and 46, nanolaminate 42 may be an asymmetric stack of layers. For example, as shown in portion 47 of FIG. 9, two layers 46 may be stacked on one another and/or two layers 44 may be stacked on one another. Forming nanolaminate 42 as an asymmetric stack of layers 44 and layers 46 may allow for the optical properties of nanolaminate 42 to be tuned.

Nanolaminate 42 may be formed entirely with alternating layers (e.g., as shown in portion 45), may be formed entirely asymmetrically (e.g., as shown in portion 47), or may be formed with alternating portions and asymmetric portions.

In some embodiments, nanolaminate 42 may incorporate or terminate with an oxide material such as CrOx, TiOx, or a gradient composition between two composite materials. For example, nanolaminate 42 may terminate with layer 48, which may be formed from CrOx, TiOx, or a gradient composition between two composite materials (e.g., SiON between SiO₂ and SiN layers). Layer 48 may have a thickness of at least 3 nm, of less than 10 nm, of less than 25 nm, of between 3 nm and 20 nm, or another suitable thickness. In other words, layer 48 may have a nanoscale thickness. Terminating nanolaminate 42 with layer 48 may allow for stronger adhesion between nanolaminate 42 and surrounding layers (e.g., surrounding layers in coating 28 and/or a substrate on which coating 28 is formed).

Although layer 48 is shown as being formed at the bottom of nanolaminate 42, this is merely illustrative. In general, layer 48 may be formed at the top of nanolaminate 42, the bottom of nanolaminate 42, and/or within the stackup of nanolaminate 42.

The layers of nanolaminate 42 (e.g., layers 44 and 46) may be varied with different levels of compressive and tensile stress, if desired. By modifying the stress of each layer, the overall stress profile of nanolaminate 42 may be engineered as desired.

Although not shown in FIG. 9, one or more quasi-ductile materials may be incorporated into nanolaminate 42. These materials may include metals and/or amorphous carbon. By incorporating one or more of these quasi-ductile materials in nanolaminate 42, the stress of nanolaminate 42 and/or crack propagation in nanolaminate 42 may be reduced.

Layers 42, layers 46, layer(s) 48, and/or other layers in nanolaminate 42 may be deposited using physical vapor deposition (PVD), atomic layer deposition (ALD), chemical vapor deposition (CVD), and/or other suitable deposition methods. Nanolaminate 42 may have a total thickness of between 8 nm and 1800 nm, of less than 100 nm, of less than 1000 nm, of at least 10 nm, of between 25 nm and 50 nm, of less than 500 nm, or another suitable thickness.

As discussed, nanolaminate 42 may replace one or more of the layers of coating 28, such as coating 28 (FIG. 4), hardcoat layer 29 and/or anti-reflective layer 34 (FIG. 5), anti-reflective layer 36 and/or hardcoat layer(s) 29A/B (FIG. 6), anti-reflective layer 38 and/or hardcoat layer 29 (FIG. 7), and/or hardcoat layer 29 and/or anti-reflective layer(s) 40A/B (FIG. 8). In some implementations, nanolaminate 42 may form an outermost layer of coating 28 (e.g., may replace one of the outermost layers of coating 28 in FIGS. 4-8), allowing as nanolaminate 42 may provide improved optical properties and hardness properties.

Although not shown in FIGS. 4-9, a buffer layer, such as buffer layer 30 of FIG. 3C, may be formed between hardcoat and anti-reflective coating 28 and housing portion 12W. Additionally, hardcoat and anti-reflective coating 28 may be applied uniformly across housing portion 12W (as shown in FIG. 3A) or may be tapered across one or more curved portions of housing portion 12W (as shown in FIG. 3B).

Although coating 28 has been described as being formed on an electronic device housing wall or housing portion, such as housing wall 12W, this is merely illustrative. In general, coating 28 may be formed on any suitable apparatus having a curved substrate, such as a curved glass layer. In this way, coating 28 may protect the curved substrate of the apparatus from scratching while reducing reflections from the curved substrate.

The foregoing is merely illustrative and various modifications can be made to the described embodiments. The foregoing embodiments may be implemented individually or in any combination.

What is claimed is:

1. An electronic device having an interior, the electronic device comprising:
a housing that separates the interior from an exterior, wherein the housing comprises a curved housing wall with a first surface that faces the interior and an opposing second surface that faces the exterior;
a display in the housing; and
a hardcoat and anti-reflective coating on the second surface of the curved housing wall.

2. The electronic device of claim 1, wherein the hardcoat and anti-reflective coating has a uniform thickness across the curved housing wall.

3. The electronic device of claim 1, wherein the curved housing wall comprises a curved edge, and the hardcoat and anti-reflective coating has a tapered thickness at the curved edge.

4. The electronic device of claim 1, further comprising:
a buffer layer interposed between the hardcoat and anti-reflective coating, wherein the buffer layer is directly on the second surface, and the hardcoat and anti-reflective coating is directly on the buffer layer.

5. The electronic device of claim 1, wherein the hardcoat and anti-reflective coating is a single layer hardcoat.

6. The electronic device of claim 5, wherein the single layer hardcoat comprises a silicon aluminum oxynitride, a silicon oxynitride, or a silicon aluminum nitride.

7. The electronic device of claim 1, wherein the hardcoat and anti-reflective coating comprises a hardcoat layer and an anti-reflective layer.

8. The electronic device of claim 7, wherein the hardcoat layer is interposed between the curved housing wall and the anti-reflective layer.

9. The electronic device of claim 8, wherein the hardcoat layer is a first hardcoat layer, the hardcoat and anti-reflective coating comprises a second hardcoat layer on the anti-reflective layer, and the anti-reflective layer is interposed between the first hardcoat layer and the second hardcoat layer.

10. The electronic device of claim 7, wherein the anti-reflective layer is interposed between the curved housing wall and the hardcoat layer.

11. The electronic device of claim 7, wherein the anti-reflective layer is a first anti-reflective layer, the hardcoat and anti-reflective coating further comprises a second anti-reflective layer, and the hardcoat is interposed between the first anti-reflective layer and the second anti-reflective layer.

12. The electronic device of claim 1, wherein the hardcoat and anti-reflective coating includes a nanolaminate.

13. The electronic device of claim 12, wherein the nanolaminate includes alternating layers with high and low refractive indexes, and wherein the alternating layers have thickness of 25 nm or less.

14. The electronic device of claim 13, wherein the alternating layers comprise SiO₂ layers and SiN layers.

15. The electronic device of claim 13, wherein the nanolaminate forms an outermost layer of the hardcoat and anti-reflective coating.

16. An electronic device, comprising:
a housing including a surface with a curved portion;
a display in the housing; and
a hardcoat and anti-reflective coating on the surface of the housing, wherein the hardcoat and anti-reflective coating has a tapered thickness across the curved portion of the surface.

17. The electronic device of claim 16, further comprising:
a buffer layer interposed between the hardcoat and anti-reflective coating and the surface of the housing.

18. The electronic device of claim 16, wherein the hardcoat and anti-reflective coating is a single layer.

19. The electronic device of claim 16, wherein the hardcoat and anti-reflective coating comprises a hardcoat layer and an anti-reflective layer.

20. The electronic device of claim 19, wherein the hardcoat layer is interposed between the surface of the housing and the anti-reflective layer.

21. The electronic device of claim 19, wherein the anti-reflective layer is interposed between the surface of the housing and the hardcoat layer.

22. An apparatus having an interior, the apparatus comprising:
a curved glass layer, wherein the curved glass layer has a first surface that faces the interior, an opposing second surface, and a curved edge; and
a single layer hardcoat on the second surface of the curved glass layer.

23. The apparatus of claim 22, wherein the single layer hardcoat includes comprises silicon oxynitride, a silicon aluminum oxynitride, or a silicon aluminum nitride.

24. The apparatus of claim 22, wherein the single layer hardcoat has a tapered thickness across the curved edge.
